(19) United States
(12) Patent Application Publication
(10) Pub. No.: US 2003/0117778 A1
(43) Pub. Date: Jun. 26, 2003

(54) Modular jack

(76) Inventors: Iosif Korsunsky, Harrisburg, PA (US); Kevin E. Walker, Hershey, PA (US); James H. Hyland, Hummelstown, PA (US)

Correspondence Address: WEI TE CHUNG, FOXCONN INTERNATIONAL, INC., 1650 MEMOREX DRIVE, SANTA CLARA, CA, 95050, US

(21) Appl. No.: 10/033,663

(22) Filed: Dec. 26, 2001

(51) Int. Cl. H05K 7/00

(52) U.S. Cl. 361/728

(57) ABSTRACT

A modular jack (1) assembled on a mother board comprises an insulative housing (2) with a receiving space (25, 26), a plurality of terminals (3, 4) received in the receiving space, and an electronic component (5, 6) assembled in the insulative housing for eliminating noise. The electronic component comprises a plurality of upper contacts (501, 601) for connecting with corresponding terminals and a plurality of lower contacts (503, 603) for connecting with the mother board.

### BACKGROUND OF THE INVENTION

1. Field of the Invention

The present invention relates to a modular jack, and particularly to a modular jack with an electronic component that can eliminate noise.

2. Description of Related Art

Modular jack is widely used to connect a complementary plug connector with a mating printed circuit board (PCB) to transmit voice signals, or any other signals. During signal transmission of a conventional modular jack, noise may cause a problem. In order to eliminate the noise in transmitting signals, electronic components for eliminating noise, such as capacitors, resistors and inductors are often provided on the mating PCB on which the modular jack is mounted. However, the electronic components will occupy a large space on the PCB. In order to reduce the occupied space, a modular jack with a built-in electronic component that is separately provided from the PCB is desired. U.S. Pat. Nos. 5,015,204, 5,282,759 and 5,069,641 each disclose a modular jack with a filter element assembled in the modular jack to eliminate noise. Since the electronic component is assembled in the modular jack and separated from the PCB, the area of the PCB is saved. However, in one of the prior art references, terminals of the modular jack are integral with wires wound around cores of the electronic component. When the electronic component or one of the terminals is broken, both the electronic component and the terminals have to be replaced. It would waste not only time, but also cost.

Hence, an improved modular jack with a replaceable electronic component is required to overcome the disadvantages of the conventional modular jack.

### SUMMARY OF THE INVENTION

Accordingly, the object of the present invention is to provide a modular jack with an electronic component which can be conveniently replaced.

In order to achieve the object set forth, a stacked modular jack assembled on a mother board comprises an insulative housing with a pair of upper and lower opposite receiving spaces, a pair of upper and lower opposite terminal modules respectively assembled in the upper and lower receiving spaces, and a pair of front and rear electronic components assembled in the insulative housing for eliminating noise. Each of the front and rear electronic components comprises a main base, a magnetic coil assembled on the main base and a filter PCB assembled on the main base. The main base comprises a plurality of upper contacts for connecting with corresponding terminals and the magnetic coil, a plurality of middle contacts for connecting with the filter PCB and the magnetic coil, and a plurality of lower contacts for connecting the filter PCB and the mother board. The modular jack connects with the mother board by the magnetic coil and the filter PCB thereby eliminating noise.

Other objects, advantages and novel features of the invention will become more apparent from the following detailed description when taken in conjunction with the accompanying drawings.

### BRIEF DESCRIPTION OF THE DRAWINGS

FIG. 1 is a perspective, exploded view of a modular jack of the present invention;

FIG. 2 is an enlarged, perspective view of a pair of terminal modules in FIG. 1;

FIG. 3 is an enlarged, front view of a pair of electronic components in FIG. 1;

FIG. 4 is an enlarged, rear view of the pair of electronic components in FIG. 1;

FIG. 5 is a cross-sectional view of the modular jack of FIG. 1; and

FIG. 6 is a cross-sectional view of a modular jack according to another embodiment of the present invention.

### DETAILED DESCRIPTION OF THE INVENTION

Reference will now be made to the drawing figures to describe the present invention in detail.

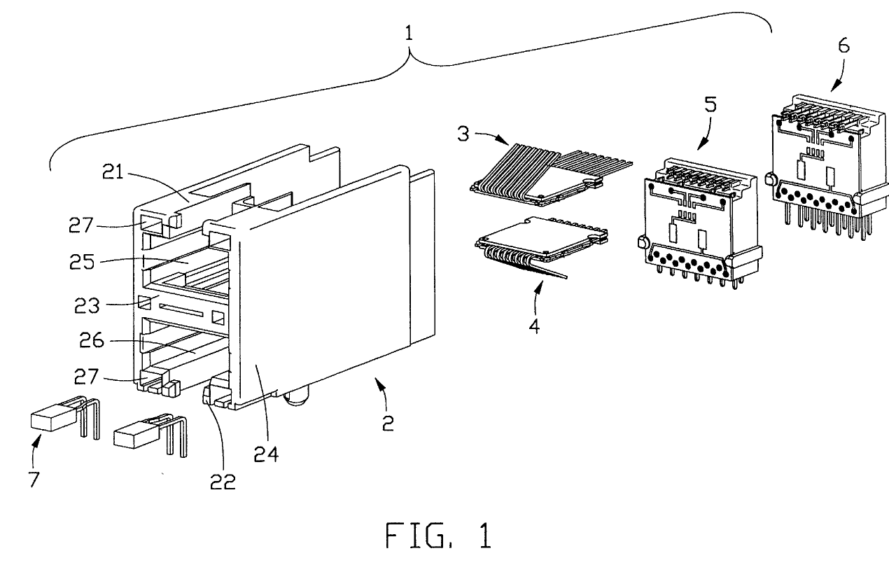

Referring to FIG. 1, a stacked modular jack 1 in accordance with the present invention comprises an insulative housing 2, a pair of opposite upper and lower terminal modules 3, 4 assembled in the insulative housing 2, a pair of front and rear electronic components 5, 6 assembled in the insulative housing 2, and four light emitting diodes 7 (LEDs) (only shown two lower ones) assembled in the insulative housing 2.

The insulative housing 2 comprises a top wall 21, an opposite bottom wall 22, a middle wall 23 between the top wall 21 and the bottom wall 22, and a pair of side walls 24. The top wall 21, the middle wall 23, the bottom wall 22 and the side walls 24 together define a pair of opposite upper and lower receiving spaces 25, 26 for respectively receiving complementary plug connectors (not shown) and the upper and lower terminal modules 3, 4. In addition, the insulative housing 2 defines four recesses 27 for receiving the LEDs 7.

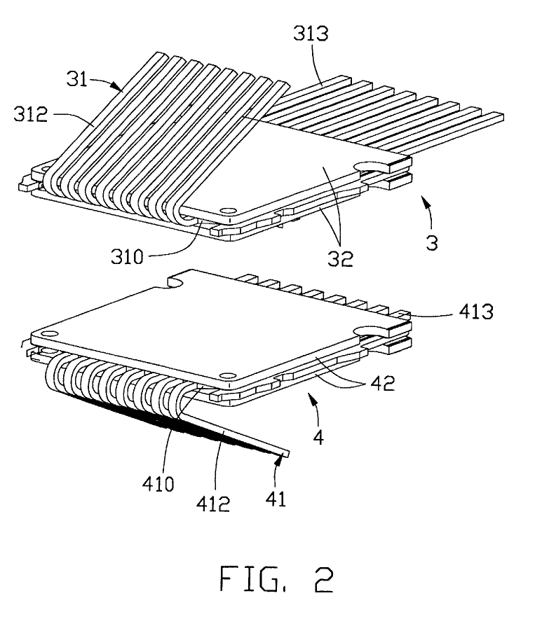

Referring to FIG. 2, the upper (lower) terminal module 3 (4) comprises a pair of opposite printed circuit boards (PCBs) 32 (42) and a plurality of terminals 31 (41). Each of the terminals 31 (41) comprises a mounting portion 310 (410) sandwiched between the PCBs 32 (42), an inclined contacting portion 312 (412) extending upwardly (downwardly) from a front end of the mounting portion 310 (410) and a tail portion 313 (413) extending rearwardly from a rear end of the mounting portion 310 (410). It should be noted that the tail portion 313 of the upper terminal module 3 is longer than the tail portion 413 of the lower terminal module 4.

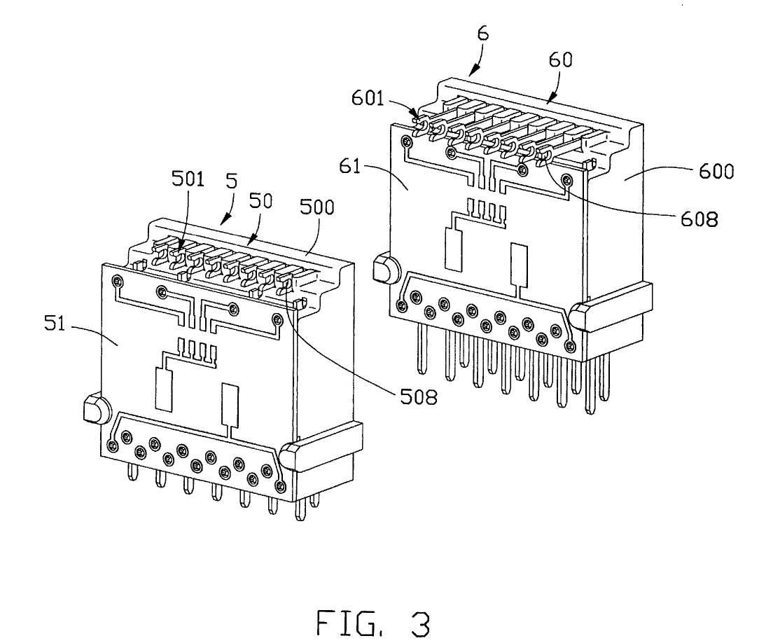

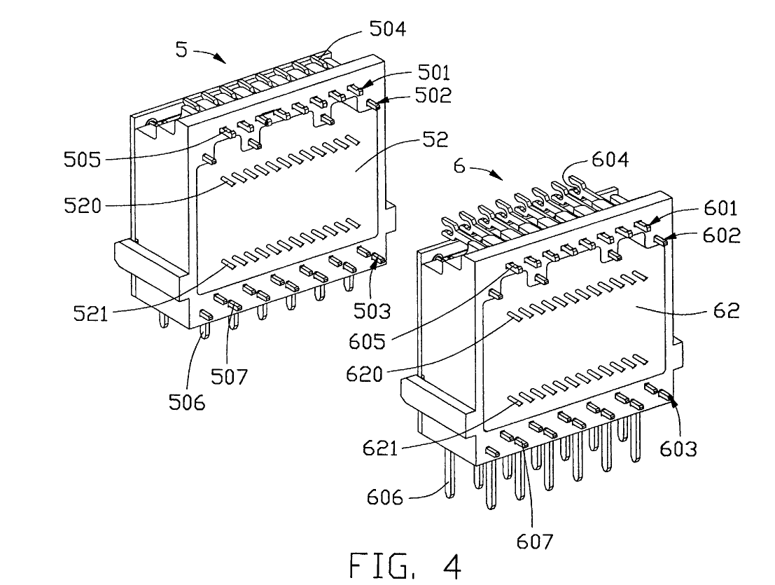

Referring to FIGS. 3 and 4, the front (rear) electronic component 5 (6) comprises a main base 50 (60), a filter PCB 51 (61) with a plurality of resistors and inductors thereon assembled on the main base 50 (60) and a magnetic coil 52 (62). The main base 50 (60) comprises a dielectric base 500 (600), eight upper contacts 501 (601) insert molded with the dielectric base 500 (600), four middle contacts 502 (602) inserted into or insert molded with the dielectric base 500 (600) and thirteen lower contacts 503 (603) inserted into or insert molded with the dielectric base 500 (600). Each of the upper contacts 501 (601) comprises a front fork-shaped mating portion 504 (604), and a connecting portion 505 (605) for connecting with corresponding upper wires 520 (620) of the magnetic coil 52 (62). Each of the front forked-shaped mating portion 504 (604) defines a receiving groove 508 (608) for snugly receiving a corresponding tail portion 413 (313) of the terminal 41 (31). Each of the lower contacts 503 (603) comprises a solder tail 506 (606) extending downwardly for soldering on the mother board and a connecting portion 507 (607) extending rearwardly for connecting with lower wires 521 (621) of the magnetic coil 52 (62).

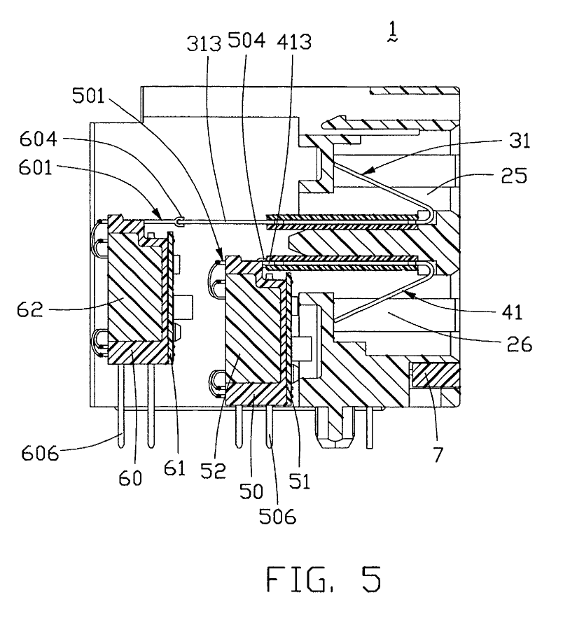

Also referring to FIG. 5, in assembly, the filter PCB 51 (61) is assembled on the main base 50 (60) of the front (rear) electronic component 5 (6) with the middle contacts 502 (602) and lower contacts 503 (603) connecting with corresponding circuits on the filter PCB 51 (61). The magnetic coil 52 (62) is assembled in the main base 50 (60) with upper and lower wires 520, 521 (620, 621) of the magnetic coil 52 (62) connecting with corresponding connecting portions 505 (605), 507 (607) of the upper and lower contacts 501 (601), 503 (603). Subsequently, the front and rear electronic components 5, 6 are respectively assembled on the upper and lower terminal modules 3, 4 with the front fork mating portions 504, 604 of the upper contacts 501, 601 connecting with the tail portions 413, 313 of the terminals 41, 31. Then, the upper (lower) terminal module 3 (4) with the rear (front) electronic component 6 (5) is inserted into the upper (lower) receiving space 25 (26). The LEDs 7 are assembled in the recesses 27 of the insulative housing 2. Finally, the modular jack 1 is assembled on the mother board with the solder tails 506 (606) of the electronic components 5 (6) soldering on the mother board. Thus, the terminals 31 (41) of the modular jack 1 and the mother board may achieve an electrical connection through the magnetic coil 62 (52) and filter PCB 61 (51), thereby eliminating noise. Although the preferred embodiment of the present invention doesn't show an outer shield, it should be noted that the outer shield may be employed to enclose the insulative housing 2 for enhanced EMI protection.

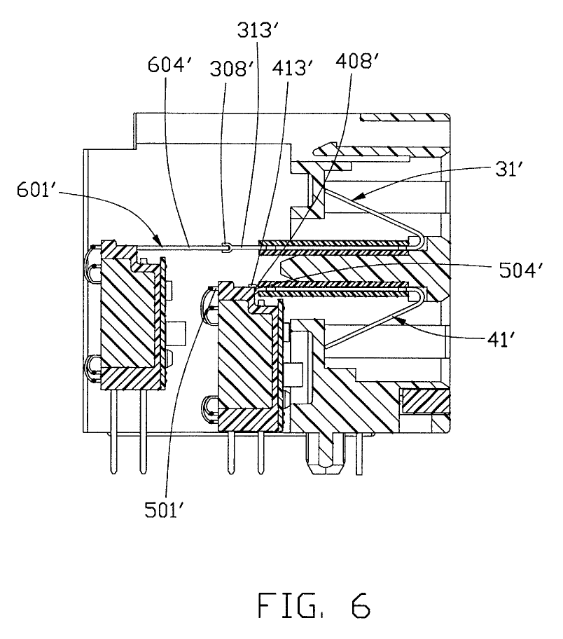

FIG. 6 illustrates an alternative embodiment of the present invention. In this embodiment, a tail portion 313′ (413′) of each terminal 31′ (41′) is fork-shaped and defines a groove 308′ (408′). A front mating portion 504′ (604′) of each upper contact 501′ (601′) is straight shaped. The front mating portion 501′ (601′) is securely inserted into the receiving groove 408′ (308′) to connect with corresponding tail portion 413′ (313′). The other components are the same as the first embodiment described above; thus, a detailed description thereof is omitted here. In addition, the modular jack may be singular rather than stacked. Also, the terminals may be insert molded in an ordinary insulative base rather than sandwiched between PCBs. Alternatively, the terminals also may be soldered to a single PCB.

In the present invention, the front and rear electronic components 5, 6 with filter PCBs 51, 61 and the magnetic coils 52, 62 are separately provided for terminal modules 3, 4, and may be replaced conveniently as desired.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A modular jack mounted on a mother board, comprising:
an insulative housing defining a receiving space;
a terminal module received in the receiving space and comprising a plurality of terminals, each terminal comprising a mounting portion, an inclined contacting portion extending from a front end of the mounting portion and a tail portion extending rearwardly from a rear end of the mounting portion; and
an electronic component assembled in the insulative housing to eliminate noise and comprising a plurality of upper contacts for connecting with the tail portions of the terminals, and a plurality of lower contacts for connecting with the mother board.

2. The modular jack as described in claim 1, wherein each of the upper contacts of the electronic component comprises a fork-shaped mating portion defining a receiving groove for receiving corresponding tail portion of the terminal.

3. The modular jack as described in claim 1, wherein the tail portion of each terminal is fork-shaped and defines a receiving groove for snugly receiving a corresponding upper contact.

4. The modular jack as described in claim 1, wherein the electronic component comprises a main base for retaining the upper and lower contacts, a plurality of middle contacts mounted on the main base, a filter printed circuit board assembled on the main base for connecting with the lower contacts and the middle contacts and a magnetic coil assembled on the main base for connecting with the upper contacts, the middle contacts and the lower contacts.

5. A modular jack assembly comprising:
an insulative housing defining upper and lower receiving spaces and a rear receiving space therein;
upper and lower terminal modules respectively disposed in the corresponding upper and lower receiving spaces with a plurality of contacts thereof;
a pair of electronic components retainably spatially located in said rear space, each of said electronic components including a base with a filter printed circuit board and magnetic coil, a plurality of upper contacts located on an upper portion of the base and engaged with the corresponding contacts, respectively, and a plurality of lower contacts located on a lower portion of the base and extending downwardly beyond a bottom face of the assembly to assemble to a main printed circuit board on which the assembly is seated.
